(19) United States
(12) Patent Application Publication
(10) Pub. No.: US 2009/0211636 A1
(43) Pub. Date: Aug. 27, 2009

(54) SOLAR CELL FOCUSING DEVICE

(76) Inventor: CHIEN-FENG LIN, Hsinchu City (TW)

Correspondence Address: WPAT, PC;INTELLECTUAL PROPERTY ATTORNEYS, 2030 MAIN STREET, SUITE 1300, IRVINE, CA, 92614, US

(21) Appl. No.: 12/037,710

(22) Filed: Feb. 26, 2008

(51) Int. Cl. H01L 31/00

(52) U.S. Cl. 136/259

(57) ABSTRACT

A solar cell focusing device includes a concave and a convex section for focusing sunlight. The concave section is provided at a predetermined position with a through hole, and the convex section is disposed opposite to the concave section with a convex surface of the convex section facing toward a concave surface of the concave section. Therefore, more solar energy from sunlight may be concentrated on a solar cell disposed behind the concave section.

### FIELD OF THE INVENTION

The present invention relates to a solar cell focusing device, and more particularly to a solar cell focusing device that utilizes opposite concave section and convex section to effectively focus sunlight on a solar cell disposed behind the concave section.

### BACKGROUND OF THE INVENTION

A conventional solar cell focusing device, as shown in FIG. 1, includes a transparent semispherical light-gathering hood 5 disposed above a solar cell 4. Sunlight 3 transmitted through the transparent semispherical light-gathering hood 5 is refracted and then concentrated on the solar cell 4. Therefore, the transparent light-gathering hood 5 functions to concentrate increased amount of sunlight 3 on the solar cell 4, so that more electric energy may be converted from the solar energy. However, since the sunlight 3 will become scattered when it transmits through the transparent semispherical hood 5, some part of the sunlight 3 is not concentrated on the solar cell 4. In addition, sunlight 3 incident on the transparent semispherical hood 5 at a position farther away from a normal line of the solar cell 4 has a relative small amount of component of light that is perpendicularly projected onto the solar cell 4. Therefore, while there is sunlight concentrated on the solar cell 4, only a small amount of the sunlight 3 is absorbed by the solar cell 4.

It is therefore tried by the inventor to develop a solar cell focusing device for concentrating more solar energy on a solar cell.

### SUMMARY OF THE INVENTION

A primary object of the present invention is to provide a solar cell focusing device to effectively focus more solar energy on a solar cell.

To achieve the above and other objects, the solar cell focusing device according to the present invention includes a concave section and a convex section. The concave section has a concave substrate and a concave reflective layer disposed atop the concave substrate, and is provided at a predetermined position with a through hole extending through the concave substrate and the concave reflective layer. The concave reflective layer is made of a metal material selected from the group consisting of silver, aluminum, and chrome to have a thickness larger than 100 nanometers. The convex section is disposed opposite to the concave section with a convex surface of the convex section facing toward a concave surface of the concave section, and includes a convex substrate and a convex reflective layer disposed atop the convex substrate. The convex reflective layer is made of a metal material selected from the group consisting of silver, aluminum, and chrome, and has a thickness larger than 100 nanometers.

Sunlight projected onto the concave reflective layer is reflected onto the convex reflective layer and reflected again to pass through the through hole on the concave section to focus on a solar cell disposed behind the concave section. Therefore, more solar energy may be concentrated on the solar cell.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a sectional view of a conventional solar cell focusing device;

FIG. 2 is a sectional view of a solar cell focusing device according to a preferred embodiment of the present invention;

FIG. 3 is a broken-line graph showing the curves of reflectivity versus reflective layer thickness obtained from experiments conducted on different metals used in the solar cell focusing device according to the preferred embodiment of the present invention;

FIG. 4 is a broken-line graph showing the curves of heat dissipation rate versus reflective layer thickness obtained from experiments conducted on different metals used in the solar cell focusing device according to the preferred embodiment of the present invention;

FIG. 5 is a broken-line graph showing the curves of strain rate versus reflective layer thickness obtained from experiments conducted on different metals used in the solar cell focusing device according to the preferred embodiment of the present invention;

FIG. 6 is a broken-line graph showing the curves of heat dissipation rate versus transparent layer thickness obtained from experiments conducted on different materials used in the solar cell focusing device according to the preferred embodiment of the present invention; and

FIG. 7 is a broken-line graph showing the curves of strain rate versus transparent layer thickness obtained from experiments conducted on different materials used in the solar cell focusing device according to the preferred embodiment of the present invention.

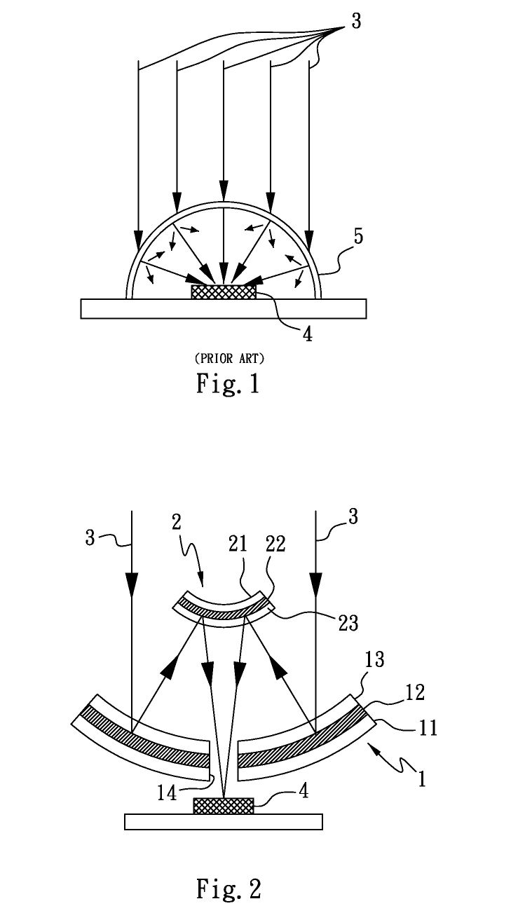

### DETAILED DESCRIPTION OF THE PREFERRED EMBODIMENTS

Please refer to FIG. 2 that is a sectional view of a solar cell focusing device according to a preferred embodiment of the present invention. As shown, the solar cell focusing device of the present invention includes a concave section 1 and a convex section 2.

The concave section 1 includes a concave substrate 11 and a concave reflective layer 12. The concave substrate 11 may be made of a polymeric material, such as a plastic material; and the concave reflective layer 12 may be made of a metal material, such as silver, aluminum, or chrome.

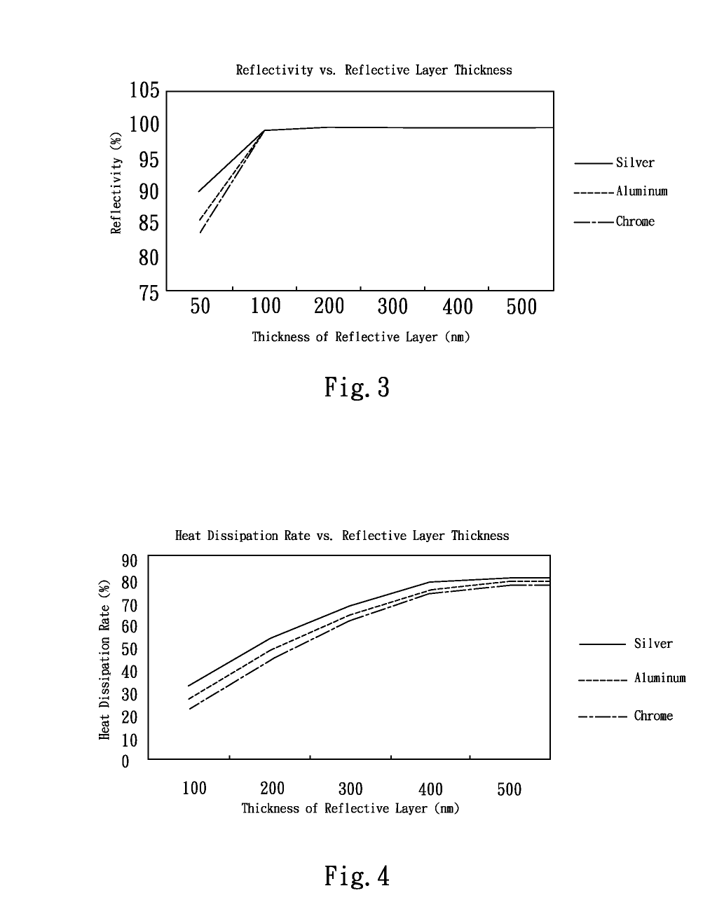

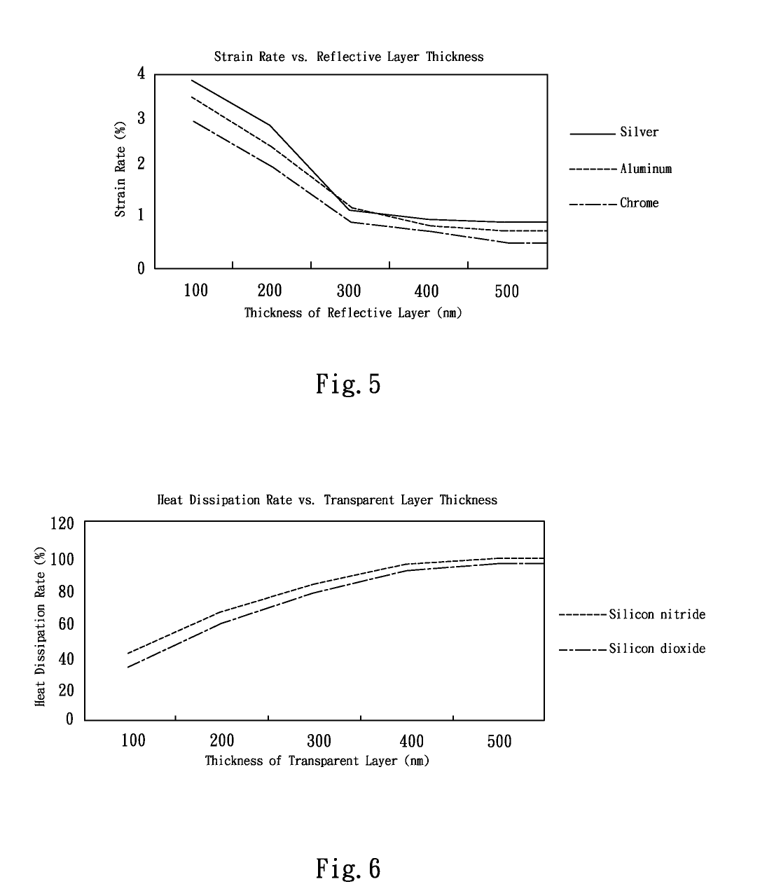

Please refer to FIGS. 3, 4, and 5. When the concave reflective layer 12 made of any of the silver, the aluminum, and the chrome has a thickness larger than 100 nanometers, both the reflectivity and the heat dissipation rate of the concave reflective layer 12 gradually increase while the strain rate of the concave reflective layer 12 gradually decreases; and when the concave reflective layer 12 made of any of the silver, the aluminum, and the chrome has a thickness larger than 500 nanometers, the reflectivity, the heat dissipation rate, and the strain rate of the silver, aluminum, and chrome reflective layers all become stable without further changes. Therefore, the concave reflective layer 12 preferably has a thickness of 500 nanometers. That is, the concave reflective layer 12 may have a thickness ranging from 100 to 500 nanometers to provide high reflectivity and high heat dissipation ability while have low strain. Therefore, the concave reflective layer 12 of the present invention may reflect more sunlight absorbed by it, and heat from the absorbed sunlight may quickly dissipate from the concave reflective layer 12. And, even if the concave reflective layer 12 is thermally expanded due to heat absorption, its deformation is small and uniform without causing any change in the reflection angle thereof.

The concave reflective layer 12 is disposed atop the concave substrate 11. The concave section 1 is provided at a predetermined position with a through hole 14, which extends through the concave substrate 11 and the concave reflective layer 12.

The convex section 2 is disposed opposite to the concave section 1 with a convex surface of the convex section 2 facing toward a concave surface of the concave section 1. The convex section 2 includes a convex substrate 21 and a convex reflective layer 22. The convex substrate 21 may be made of a polymeric material, such as a plastic material; and the convex reflective layer 22 may be made of a metal material, such as silver, aluminum, or chrome.

As can be seen from FIGS. 3, 4, and 5, when the convex reflective layer 22 made of any of the silver, the aluminum, and the chrome has a thickness larger than 100 nanometers, both the reflectivity and the heat dissipation rate of the convex reflective layer 22 gradually increase while the strain rate of the convex reflective layer 22 gradually decreases; and when the convex reflective layer 22 made of any of the silver, the aluminum, and the chrome has a thickness larger than 500 nanometers, the reflectivity, the heat dissipation rate, and the strain rate of the silver, aluminum, and chrome reflective layers all become stable without further changes. Therefore, the convex reflective layer 22 preferably has a thickness of 500 nanometers. That is, the convex reflective layer 22 may have a thickness ranging from 100 to 500 nanometers to provide high reflectivity and high heat dissipation ability while have low strain. Therefore, the convex reflective layer 22 of the present invention may reflect more sunlight absorbed by it, and heat from the absorbed sunlight may quickly dissipate from the convex reflective layer 22. And, even if the convex reflective layer 22 is thermally expanded due to heat absorption, its deformation is small and uniform without causing any change in the reflection angle thereof. The convex reflective layer 22 is disposed atop the convex substrate 21.

The concave section 1 may further include a concave transparent layer 13 disposed atop the concave reflective layer 12, so that the concave reflective layer 12 is better protected by the concave transparent layer 13 against oxidization. The through hole 14 also extends through the concave transparent layer 13. The concave transparent layer 13 may be made of silicon dioxide or silicon nitride.

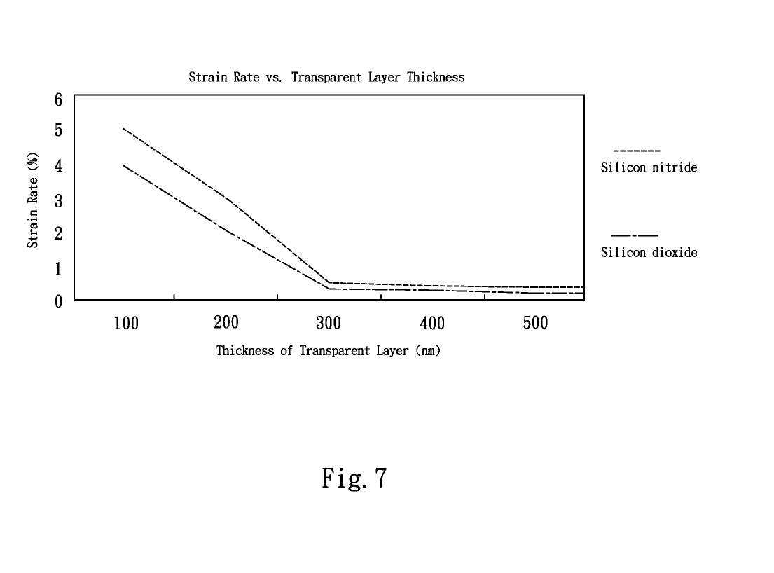

Please refer to FIGS. 6 and 7. When the concave transparent layer 13 made of any of the silicon dioxide and silicon nitride has a thickness larger than 100 nanometers, the heat dissipation rate of the concave transparent layer 13 gradually increases while the strain rate of the concave transparent layer 13 gradually decreases; and when the concave transparent layer 13 made of any of the silicon dioxide and silicon nitride has a thickness larger than 500 nanometers, the heat dissipation rate and the strain rate of the silicon dioxide and silicon nitride transparent layers all become stable without further changes. Therefore, the concave transparent layer 13 preferably has a thickness of 500 nanometers. That is, the concave transparent layer 13 may have a thickness ranging from 100 to 500 nanometers to provide high heat dissipation ability while have low strain. Therefore, heat from sunlight absorbed by the concave transparent layer 13 may quickly dissipate therefrom. And, even if the concave transparent layer 13 is thermally expanded due to heat absorption, its deformation is small and uniform without causing any change in the refraction angle thereof.

Similarly, the convex section 2 may further include a convex transparent layer 23 disposed atop the convex reflective layer 22, so that the convex reflective layer 22 is better protected by the convex transparent layer 23 against oxidization. The convex transparent layer 23 may be made of silicon dioxide or silicon nitride.

As can be seen from FIGS. 6 and 7, when the convex transparent layer 23 made of any of the silicon dioxide and silicon nitride has a thickness larger than 100 nanometers, the heat dissipation rate of the convex transparent layer 23 gradually increases while the strain rate of the convex transparent layer 23 gradually decreases; and when the convex transparent layer 23 made of any of the silicon dioxide and silicon nitride has a thickness larger than 500 nanometers, the heat dissipation rate and the strain rate of the silicon dioxide and silicon nitride transparent layers all become stable without further changes. Therefore, the convex transparent layer 23 preferably has a thickness of 500 nanometers. That is, the convex transparent layer 23 may have a thickness ranging from 100 to 500 nanometers to provide high heat dissipation ability while have low strain. Therefore, heat from sunlight absorbed by the convex transparent layer 23 may quickly dissipate therefrom. And, even if the convex transparent layer 23 is thermally expanded due to heat absorption, its deformation is small and uniform without causing any change in the refraction angle thereof.

Sunlight 3 is first reflected by the concave reflective layer 12 of the concave section 1 onto the convex section 2, and then reflected again by the convex reflective layer 22 of the convex section 2 to pass through the through hole 14 and be focused. A solar cell 4 is disposed at the focal point of the focusing device of the present invention to receive the focused sunlight 3. With the solar cell focusing device of the present invention, as much sunlight 3 as possible may be focused to almost form a light beam before the sunlight 3 is projected onto the solar cell 4. That is, the solar cell focusing device of the present invention causes all the sunlight 3 incident on the solar cell 4 to project in a direction as parallel with a normal line of the solar cell 4 as possible, so that the solar cell 4 could absorb as much solar energy from sunlight 3 as possible and convert the absorbed solar energy into more electric energy.

With the above arrangements, the solar cell focusing device of the present invention is novel, improved, and industrially practical for use. More specifically, the present invention is novel and improved because it brings sunlight to be sequentially reflected by the concave and the convex section, and then pass through the through hole on the concave section and be focused, so that more solar energy can be concentrated for use. The present invention and other products derived therefrom would no doubt fully meet the current market demands.

What is claimed is:

1. A solar cell focusing device, comprising:
a concave section having a concave substrate and a concave reflective layer disposed atop the concave substrate; the concave reflective layer being made of a metal material selected from the group consisting of silver, aluminum, and chrome, and having a thickness larger than 100 nanometers; and the concave section being provided at a predetermined position with a through hole extending through the concave substrate and the concave reflective layer; and
a convex section being disposed opposite to the concave section with a convex surface of the convex section facing toward a concave surface of the concave section; the convex section having a convex substrate and a convex reflective layer disposed atop the convex substrate; the convex reflective layer being made of a metal material selected from the group consisting of silver, aluminum, and chrome, and having a thickness larger than 100 nanometers;
whereby sunlight projected onto the concave reflective layer is reflected onto the convex reflective layer and then reflected from the convex reflective layer again to pass through the through hole on the concave section and focus on a solar cell disposed behind the concave section.

2. The solar cell focusing device as claimed in claim 1, wherein the concave section further has a concave transparent layer disposed atop the concave reflective layer, and the through hole also extends through the concave transparent layer; and the concave transparent layer being made of a material selected from the group consisting of silicon dioxide and silicon nitride, and having a thickness larger than 100 nanometers.

3. The solar cell focusing device as claimed in claim 1, wherein the convex section further has a convex transparent layer disposed atop the convex reflective layer; and the concave transparent layer being made of a material selected from the group consisting of silicon dioxide and silicon nitride, and having a thickness larger than 100 nanometers.

4. The solar cell focusing device as claimed in claim 1, wherein the concave substrate is made of a polymeric material.

5. The solar cell focusing device as claimed in claim 1, wherein the convex substrate is made of a polymeric material.

6. The solar cell focusing device as claimed in claim 1, wherein the concave reflective layer preferably has a thickness of 500 nanometers.

7. The solar cell focusing device as claimed in claim 1, wherein the convex reflective layer preferably has a thickness of 500 nanometers.

8. The solar cell focusing device as claimed in claim 2, wherein the concave transparent layer preferably has a thickness of 500 nanometers.

9. The solar cell focusing device as claimed in claim 3, wherein the convex transparent layer preferably has a thickness of 500 nanometers.
